(19) United States
(12) Patent Application Publication
(10) Pub. No.: US 2024/0429164 A1
(43) Pub. Date: Dec. 26, 2024

(54) INTEGRATED CIRCUIT DEVICES WITH FLIPPED STAIRCASE INTERCONNECT STRUCTURES

(71) Applicant: Intel Corporation, Santa Clara, CA (US)

(72) Inventor: Abhishek A. Sharma, Portland, OR (US)

(73) Assignee: Intel Corporation, Santa Clara, CA (US)

(21) Appl. No.: 18/338,395

(22) Filed: Jun. 21, 2023

(51) Int. Cl. H01L 23/528; H01L 23/00; H01L 23/522; H01L 23/532

(52) U.S. Cl. CPC H01L 23/5283; H01L 23/5226; H01L 23/5329; H01L 24/08; H01L 2224/0401; H01L 2224/05647; H01L 2224/08146; H01L 2224/80895; H01L 2924/13091; H01L 2924/1811

(57) ABSTRACT

An example IC device includes a support structure; a device layer over or at least partially in the support structure, the device layer comprising transistors; and an interconnect layer. The device layer is between the support structure and the interconnect layer, and the interconnect layer includes a first conductive line and a second conductive line stacked above the first conductive line. A first end of the first conductive line is substantially aligned with a first end of the second conductive line along a plane perpendicular to the substrate, and a second end of the first conductive line is closer to the plane than a second end of the second conductive line. Such an arrangement of conductive lines may be referred to as “flipped staircase.”

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### BRIEF DESCRIPTION OF THE DRAWINGS

Embodiments will be readily understood by the following detailed description in conjunction with the accompanying drawings.

FIG. 1 provides a block diagram of an integrated circuit (IC) device with a flipped staircase interconnect structure bonded to a metal layer, according to some embodiments of the present disclosure.

FIG. 2 provides a block diagram of an IC device with a flipped staircase interconnect structure bonded to a device layer, according to some embodiments of the present disclosure.

FIGS. 3-8 illustrate cross-sectional side views during fabrication of an IC device with a flipped staircase interconnect structure, according to some embodiments of the present disclosure.

FIG. 9 illustrates a cross-sectional side view of an example IC device with a flipped staircase interconnect structure bonded to a metal layer, according to some embodiments of the present disclosure.

FIG. 10 illustrates a cross-sectional side view of an example IC device with a flipped staircase interconnect structure bonded to a device layer, according to some embodiments of the present disclosure.

FIG. 12 is a cross-sectional side view of an IC package that may include an IC device with one or more flipped staircase interconnect structures in accordance with any of the embodiments disclosed herein.

FIG. 13 is a cross-sectional side view of an IC device assembly that may include an IC device with one or more flipped staircase interconnect structures in accordance with any of the embodiments disclosed herein.

FIG. 14 is a block diagram of an example computing device that may include an IC device with one or more flipped staircase interconnect structures in accordance with any of the embodiments disclosed herein.

FIG. 15 is a block diagram of an example processing device that may include an IC device with one or more flipped staircase interconnect structures in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC devices with flipped staircase interconnect structures as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

IC fabrication usually includes two stages. The first stage is referred to as the front-end of line (FEOL). The second stage is referred to as the back-end of line (BEOL). In the FEOL, individual semiconductor devices components (e.g., transistor, capacitors, resistors, etc.) can be patterned in a wafer. In the BEOL, interconnect structures such as conductive lines and conductive vias, separated as needed by an insulator material, can be formed to get the individual components interconnected. The BEOL usually starts with forming the first metal layer on the wafer. The first metal layer is often called M0. More metal layers can be formed on top of M0, and these metal layers are often called M1, M2, and so on.

Embodiments of the present disclosure are based on recognition that building the BEOL directly over the FEOL may have disadvantages in terms of the density and arrangement of the interconnect structures. To improve on these, IC devices that include flipped staircase interconnect structures are disclosed. An example IC device includes a support structure (e.g., a substrate, a die, a wafer, or a chip); a device layer over or at least partially in the support structure, the device layer comprising a plurality of transistors (e.g., the device layer may be a FEOL layer or one of the BEOL layers); and an interconnect layer. In such an IC device, the device layer is between the support structure and the interconnect layer, and the interconnect layer includes a first conductive line and a second conductive line stacked above the first conductive line (i.e., the second conductive line is further away from the device layer than the first conductive line). A first end of the first conductive line is substantially aligned with a first end of the second conductive line along a plane perpendicular to the substrate, and a second end of the first conductive line is closer to the plane than a second end of the second conductive line (i.e., the length of the first conductive line is smaller than the length of the second conductive line). An arrangement of conductive lines stacked above one another and having their first ends aligned along a single plane perpendicular to a support structure while having their lengths gradually decrease the closer they get to the support structure may be referred to as “flipped staircase” because in a normal (i.e., not flipped) staircase the lengths of the conductive lines of a stack would increase the closer they get to the support structure.

Various IC devices with flipped staircase interconnect structures as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting” can also mean “optically conducting.”

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

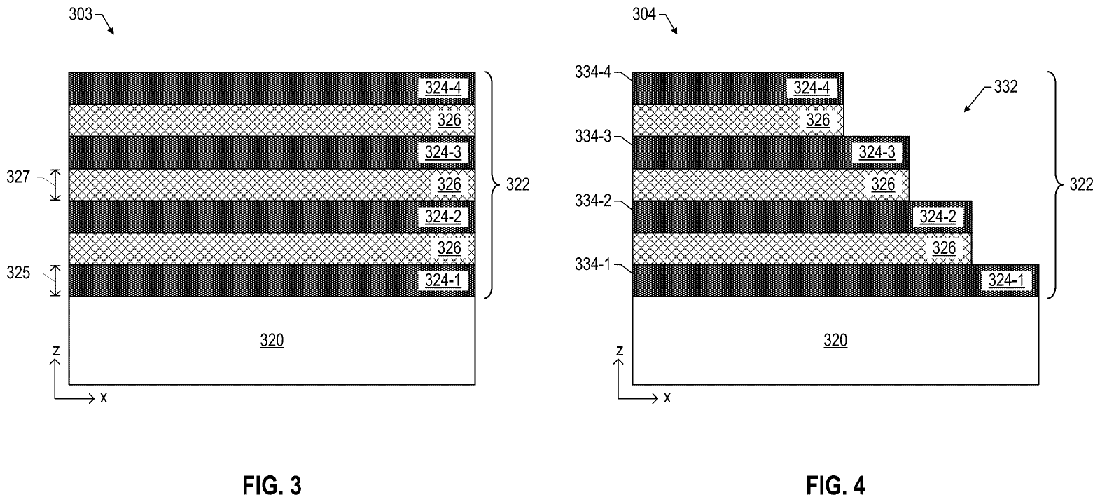

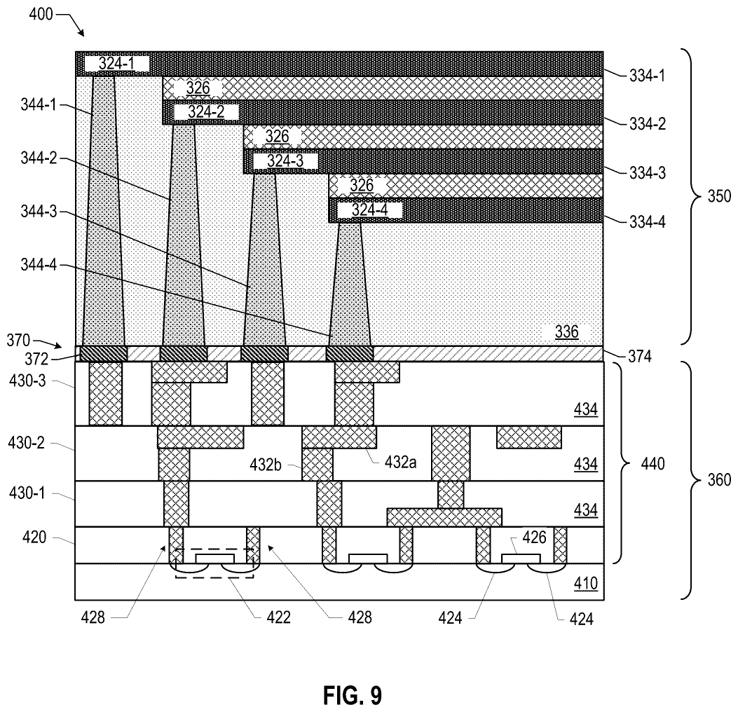

Any of the features discussed with reference to any of accompanying drawings herein may be combined with any other features to form IC devices with flipped staircase interconnect structures, as appropriate. A number of elements of the drawings are shared with others of the drawings; for ease of discussion, a description of these elements is not repeated, and these elements may take the form of any of the embodiments disclosed herein. If multiple instances of certain elements are illustrated, then, in some cases, to not clutter the drawings only some of these elements may be labeled with a reference sign and other ones of these elements are not labeled (e.g., although FIG. 9 illustrates three transistors 422, only one of them is labeled with a reference sign). However, in other cases, for ease of explanation, different instances of a given element in a single drawing may be referred to with numbers 1, 2, and so on, after a dash (e.g., FIG. 3 illustrates multiple electrically conductive layers 324, labeled individually as electrically conductive layers 324-1, 324-2, 324-3, and 324-4).

The drawings are not necessarily to scale. Although many of the drawings illustrate rectilinear structures with flat walls and right-angle corners, this is simply for ease of illustration and may not reflect real-life process limitations which may cause various features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The description may use the phrases “in an embodiment” or “in embodiments,” which may each refer to one or more of the same or different embodiments. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2%, of a target value based on the context of a particular value as described herein or as known in the art.

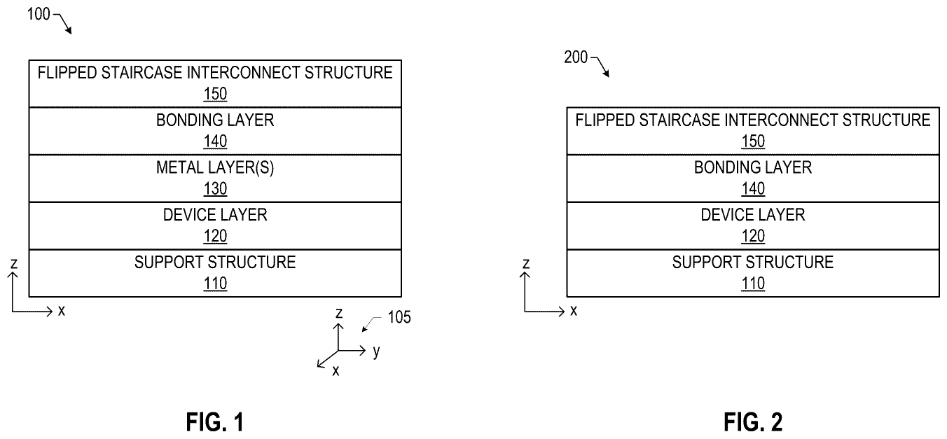

FIG. 1 illustrates a cross-sectional view of an example IC device 100 in which one or more flipped staircase interconnect structures may be implemented, according to some embodiments of the present disclosure. FIG. 1 illustrates an example coordinate system 105 with axes x-y-z so that the various planes illustrated in FIG. 1 and in some subsequent drawings may be described with reference to this coordinate system.

As shown in FIG. 1, in general, the IC device 100 may include a support structure 110, a device layer 120, metal layers 130, a bonding layer 140, and a flipped staircase interconnect structure 150, where the bonding layer 140 bonds the flipped staircase interconnect structure 150 to the top metal layer of the metal layers 130. The illustration of FIG. 1 is intended to provide a general orientation and arrangement of various layers with respect to one another, and, unless specified otherwise in the present disclosure, includes embodiments of the IC device 100 where portions of elements described with respect to one of the layers shown in FIG. 1 may extend into one or more, or be present in, other layers. One example implementation of the IC device 100 is an IC device 400, shown in FIG. 9 and described below.

The support structure 110 may be any suitable support over which the device layer 120 may be provided. For example, the support structure 110 may be a substrate, a die, a wafer or a chip. The support structure 110 may, e.g., be the wafer 2000 of FIG. 11, discussed below, and may be, or be included in, a die, e.g., the singulated die 2002 of FIG. 11, discussed below. The support structure 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure.

In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure 110 may be a printed circuit board (PCB) substrate. Although a few examples of materials from which the substrate may be formed are described here, any material that may serve as a foundation upon which a semiconductor device to be bonded to any of the flipped staircase interconnect structures as described herein may be built falls within the spirit and scope of the present disclosure.

The device layer 120 may include any combination of active ICs provided over the support structure 110. For example, in some embodiments, the device layer 120 may include various logic layers, circuits, and devices (e.g., logic transistors) to drive and control a logic IC. In some embodiments, the device layer 120 may include memory devices/circuits.

The metal layers 130 may be, or include, metal layers of a BEOL. Together, the metal layers 130 may be referred to as a “metallization stack” of the IC device 100. As used herein, the term “metal layer” may refer to a layer above a support structure 110 that includes electrically conductive interconnect structures (e.g., conductive lines and conductive vias) for providing electrical connectivity between different IC components. Metal layers described herein may also be referred to as “interconnect layers” to clearly indicate that these layers include electrically conductive interconnect structures which may, but does not have to, be metal. The metal layers 130 may be used to interconnect the various inputs and outputs of the active devices (e.g., transistors) in the device layer 120. Generally speaking, each of the metal layers 130 may include a conductive line (also sometimes referred to as a “trench,” a “trace,” or a “metal line”) and/or a conductive via. Conductive lines of a metal layer are configured for transferring signals and power along electrically conductive (e.g., metal) structures extending in the x-y plane (e.g., in the x or y directions), while the conductive vias of a metal layer are configured for transferring signals and power through electrically conductive structures extending in the z-direction, e.g., to any of the adjacent metal layers above or below. Accordingly, conductive vias connect interconnect structures (e.g., conductive lines and/or conductive vias) of one metal layer to interconnect structures of an adjacent metal layer. While referred to as “metal” layers, various layers of the metal layers 130 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD). The insulating medium may include any suitable ILD materials such as silicon oxide, carbon-doped silicon oxide, silicon carbide, silicon nitride, aluminum oxide, and/or silicon oxynitride.

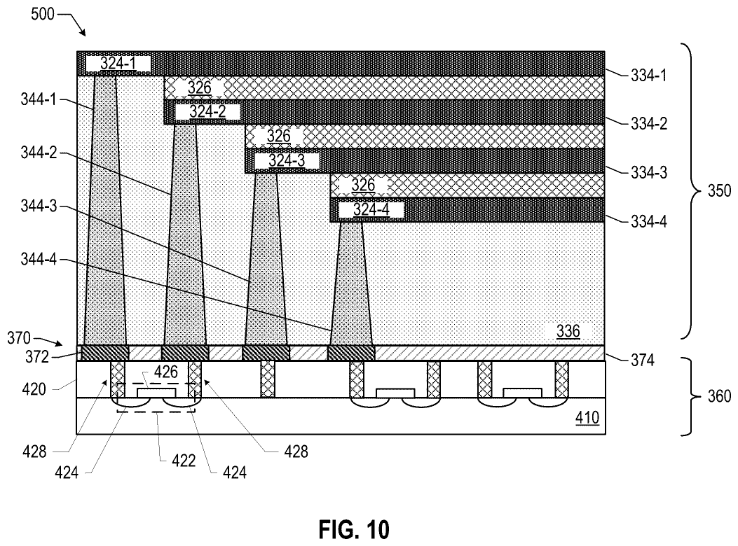

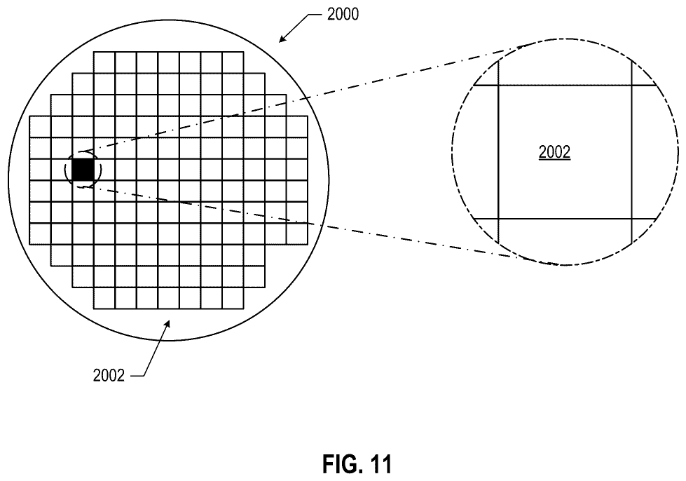

FIG. 2 illustrates a cross-sectional view of an example IC device 200 in which one or more flipped staircase interconnect structures may be implemented, according to other embodiments of the present disclosure. The IC device 200 is substantially the same as the IC device 100, except that it does not include the one or more metal layers 130 and, instead, the bonding layer 140 bonds the flipped staircase interconnect structure 150 to the device layer 120. Similar to FIG. 1, the illustration of FIG. 2 is intended to provide a general orientation and arrangement of various layers with respect to one another, and, unless specified otherwise in the present disclosure, includes embodiments of the IC device 200 where portions of elements described with respect to one of the layers shown in FIG. 2 may extend into one or more, or be present in, other layers. One example implementation of the IC device 200 is an IC device 500, shown in FIG. 10 and described below.

FIGS. 3-8 illustrate cross-sectional side views during fabrication of an IC device with a flipped staircase interconnect structure, according to some embodiments of the present disclosure. In each of FIGS. 3-8, a cross-sectional side view of an x-z plane of the coordinate system 105 is shown.

Fabrication of an IC device with a flipped staircase interconnect structures may begin with providing an IC device that includes a support structure and a stack of alternating layers of a conductive material and an insulator material. An example result of this is shown in FIG. 3, illustrating an IC device 303 that includes a support structure 320 and a stack 322 of electrically conductive layers 324 separated by insulator layers 326. Individual electrically conductive layers 324 are labeled in FIG. 3 and subsequent drawings as electrically conductive layers 324-1, 324-2, 324-3, and 324-4.

The support structure 320 may be any suitable support over which a staircase interconnect structure may be provided, to be later delaminated from the support structure 320 and flipped to form a flipped staircase interconnect structure. In some embodiments, the support structure 320 may include any of the materials of the support structure 110, described above.

The electrically conductive layers 324 may be layers of any suitable conductive metals or metal alloys, such as any metals or metal allows described above. The insulator layers 326 may be layers of any suitable insulator materials, such as any ILD materials described above. In some embodiments, any of the insulator layers 326 may be a low-k dielectric material. Examples of the low-k dielectric materials that may be used in any of insulator layers 326 include, but are not limited to, silicon dioxide, carbon-doped oxide, silicon nitride, fused silica glass (FSG), and organosilicates such as silsesquioxane, siloxane, and organosilicate glass. Other examples of low-k dielectric materials that may be used in any of the insulator layers 326 include organic polymers such as polyimide, polynorbornenes, benzocyclobutene, perfluorocyclobutane, or polytetrafluoroethylene (PTFE). Still other examples of low-k dielectric materials that may be used in any of the insulator layers 326 include silicon-based polymeric dielectrics such as hydrogen silsesquioxane (HSQ) and methylsilsesquioxane (MSQ). In some embodiments, any of the insulator layers 326 may include any suitable semiconductor material together with oxygen (i.e., any of the insulator layers 326 may be an oxide of a semiconductor material) or together with nitrogen (i.e., any of the insulator layers 326 may be a nitride of a semiconductor material), or together with oxygen and nitrogen (i.e., any of the insulator layers 326 may be an oxynitride of a semiconductor material).

Any suitable deposition technique may be used to provide the electrically conductive layers 324 alternating with the insulator layers 326 in the IC device 303, such as atomic level deposition (ALD), chemical vapor deposition (CVD), physical vapor deposition (PVD), spin-coating, dip-coating, etc. While FIG. 3 and subsequent drawings illustrate an electrically conductive layer 324-1 being the bottom layer of the stack 322, in other embodiments, an insulator layer 326 may be the bottom layer of the stack 322. While FIG. 3 and subsequent drawings illustrate a particular number of the layers of the electrically conductive layers 324 alternating with the insulator layers 326 in the stack 322, in other embodiments, the number and the arrangement of the individual layers in the stack 322 may be different.

In some embodiments, a thickness 325 of an individual electrically conductive layer 324 (i.e., a dimension measured along the z-axis of the coordinate system 105) may be between about 10 nanometers and 1000 nanometers, including all ranges and values therein, e.g., between about 20 nanometers and 750 nanometers or between about 25 nanometers and 250 nanometers. In some embodiments, a thickness 327 of an individual insulator layer 326 may be in substantially the same ranges as those described for the thickness 325. Although FIG. 3 illustrates all of the electrically conductive layers 324 and the insulator layers 326 to be of about the same thickness, this may be different in other embodiments. In general, any layers of any of the electrically conductive layers 324 and the insulator layers 326 may have the same or different thicknesses compared to any other layers.

The fabrication method may then continue with patterning the stack 322 of the IC device 303 to form a staircase arrangement of conductive lines. An example result of this is shown in FIG. 4, illustrating an IC device 304 that includes a staircase interconnect structure 332 of the electrically conductive layers 324 patterned into conductive lines 334 (individually labeled as conductive lines 334-1, 334-2, 334-3, and 334-4). A conductive line 334-1 is a line patterned from the electrically conductive layer 324-1, a conductive line 334-2 is a line patterned from the electrically conductive layer 324-2, a conductive line 334-3 is a line patterned from the electrically conductive layer 324-3, and conductive line 334-4 is a line patterned from the electrically conductive layer 324-4. In some embodiments, the insulator layers 326 under respective conductive lines 334 may be patterned in a similar manner as the conductive lines 334, as shown in FIG. 4. The arrangement 332 is referred to as a “staircase arrangement” because the lengths of the lines (dimensions measured along the x-axis of the coordinate system 105) increase from the top of the stack 322 to the bottom of the stack 322. Since the electrically conductive layers 324 have now been patterned into conductive lines 334 (I.e., their dimensions along the y-axis decreased to be suitable for a “conductive line” of an IC device), the stack 322 is now a stack of conductive lines 334.

Any suitable patterning techniques may be used to pattern the stack 322 to form the staircase interconnect structure 332 of the IC device 304, such as, but not limited to, photolithographic or electron-beam (e-beam) patterning, possibly in conjunction with a suitable etching technique, e.g., a dry etch, such as e.g., radio frequency (RF) reactive ion etch (RIE) or inductively coupled plasma (ICP) RIE. In some embodiments, the etch performed in a patterning process may include an anisotropic etch, using etchants in a form of, e.g., chemically active ionized gas (i.e., plasma) using e.g., bromine (Br) and chloride (CI) based chemistries. In some embodiments, during the etch of a patterning process, the IC structure may be heated to elevated temperatures, e.g., to temperatures between about room temperature and 200 degrees Celsius, including all values and ranges therein, to promote that byproducts of the etch are made sufficiently volatile to be removed from the surface.

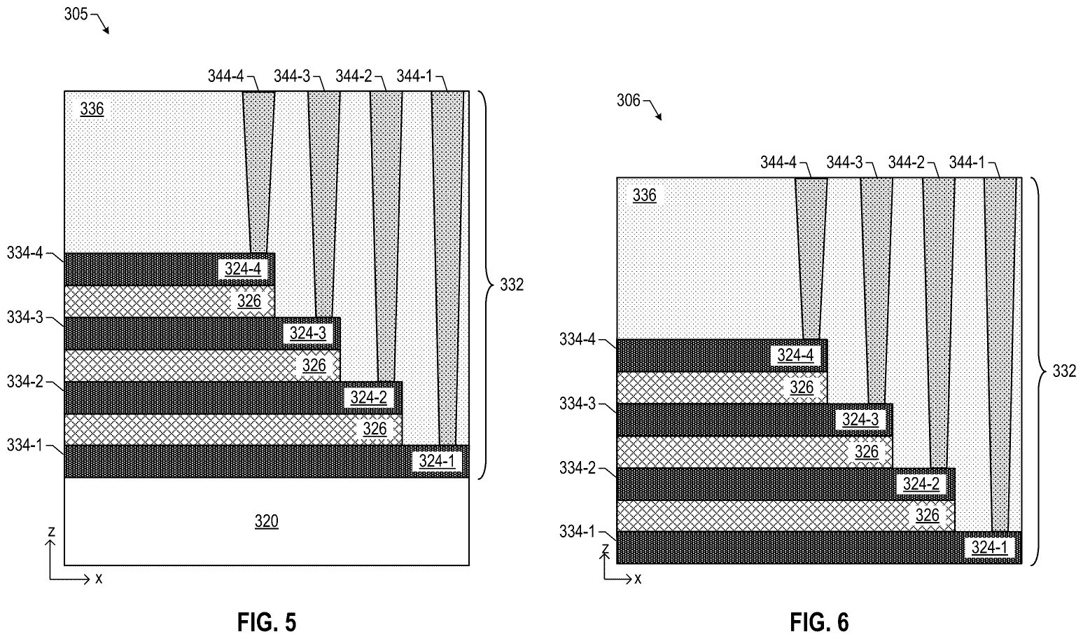

The fabrication method may then continue with providing an insulator material 336 over the staircase interconnect structure 332 and conductive vias 344 through the insulator material 336 to provide electrical connectivity to the conductive lines 334. An example result of this is shown with an IC device 305 of FIG. 5. The conductive vias 344 are individually labeled in FIG. 5 as conductive vias 344-1, 344-2, 344-3, and 344-4). A conductive via 344-1 is a via patterned through the insulator material 336 to couple to (e.g., directly connect to or be in conductive contact with) the conductive line 334-1, a conductive via 344-2 is a via patterned through the insulator material 336 to couple to the conductive line 334-2, a conductive via 344-3 is a via patterned through the insulator material 336 to couple to the conductive line 334-3, and conductive via 344-4 is a via patterned through the insulator material 336 to couple to the conductive line 334-4. The staircase interconnect structure 332 now includes the conductive lines 334 and the conductive vias 344, along with the insulator layers 326 and the insulator material 336. Any suitable patterning techniques, such as the ones described above, may be used to pattern the conductive vias 344.

Next, the fabrication method may then continue with delaminating the staircase interconnect structure 332 from the support structure 320. An example result of this is shown with an IC device 306 of FIG. 6, where the support structure 320 is no longer present.

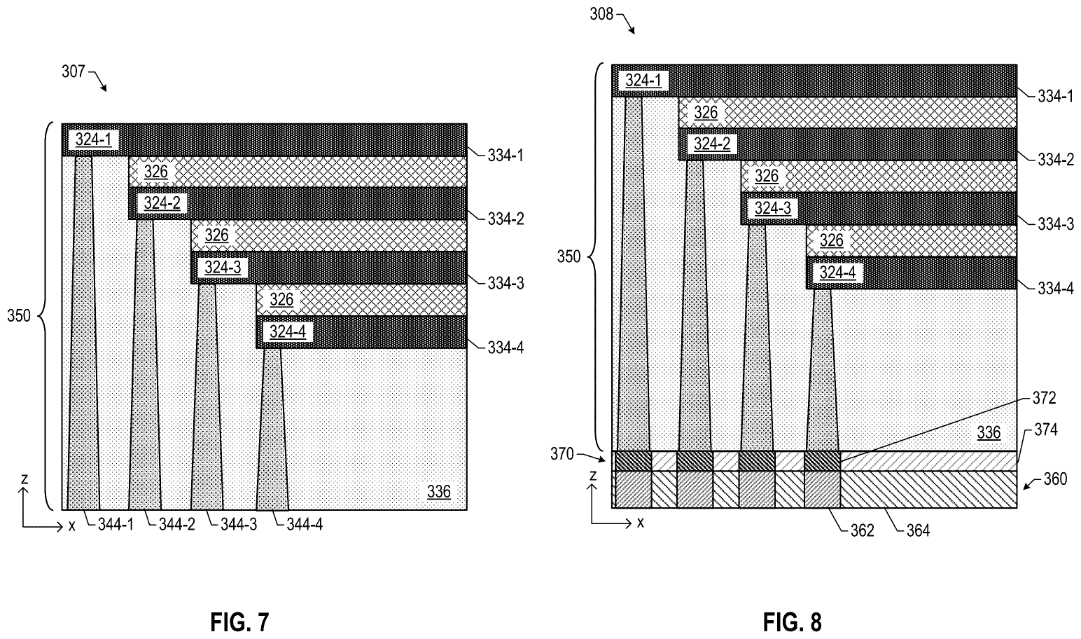

After that, the delaminated staircase interconnect structure 332 may be flipped (i.e., turned upside down). An example result of this is shown with an IC device 307 of FIG. 7, showing a flipped staircase interconnect structure 350, which is a flipped version of the staircase interconnect structure 332.

Finally, the fabrication method may include bonding the flipped staircase interconnect structure 350 to a die 360 using a bonding layer 370, an example result of which is shown with an IC device 308 of FIG. 8. In some embodiments, the bonding layer 370 may be a direct bonding (DB) layer 370. DB has attracted considerable attraction recently for coupling microelectronic components (e.g., two dies, or a die and one of a package substrate, a circuit board, or an interposer). As used herein, the term “direct bonding” is used to include metal-to-metal bonding techniques (e.g., copper-to-copper bonding, or other techniques in which DB contacts of opposing direct bonding interfaces (DB interfaces) are brought into contact first, then subject to heat and compression) and hybrid bonding techniques (e.g., techniques in which direct bonding dielectric (DB dielectric) of opposing DB interfaces, possibly first subjected to prior surface activation, are brought into contact first, then subject to heat and sometimes compression, or techniques in which the DB contacts and the DB dielectric, possibly first subjected to prior surface activation, of opposing DB interfaces are brought into contact substantially simultaneously, and the subject to heat and sometimes compression). The materials of opposing DB dielectrics can be homogeneous (i.e., have substantially the same material composition) or non-homogeneous (i.e., have different material compositions). In such techniques, the DB contacts, and the DB dielectric at one DB interface (e.g., at a DB interface of a first microelectronic component) are brought into contact with the DB contacts and the DB dielectric at another DB interface (e.g., at a DB interface of a second microelectronic component), respectively, and elevated pressures and/or temperatures may be applied to cause the contacting DB contacts and/or the contacting DB dielectrics to bond. Direct bonding may provide significant advantages over conventional coupling techniques such as solder-based interconnects or wirebonds. Direct bonding interconnects may be capable of reliably conducting a higher current than other types of interconnects; for example, some conventional solder interconnects may form large volumes of brittle intermetallic compounds when current flows, and the maximum current provided through such interconnects may be constrained to mitigate mechanical failure.

As shown in FIG. 8, the bonding layer 370 may include a bonding contacts 372 and a bonding dielectric 374 around the bonding contacts 372. The bonding layer 370 bonds (e.g., electrically and mechanically) the flipped staircase interconnect structure 350 and the die 360. For example, the bonding contacts 372 may substantially align with the conductive vias 344 of the flipped staircase interconnect structure 350 and with conductive contacts 362 at the surface of the die 360 that is facing the flipped staircase interconnect structure 350.

As described above, the term “direct bonding” is used to include metal-to-metal bonding techniques such as copper-to-copper bonding, or other techniques in which the DB contacts of opposing DB interfaces are brought into contact first, then subject to heat and compression. The term is also used to include hybrid bonding techniques such as techniques in which the DB dielectric of opposing DB interfaces, possibly first subjected to prior surface activation, are brought into contact and then subjected to heat and sometimes compression, or techniques in which the DB contacts and the DB dielectric of opposing DB interfaces, possibly first subjected to prior surface activation, are brought into contact substantially simultaneously, then subject to heat and sometimes compression. For the flipped staircase interconnect structure 350, DB contacts are ends of the conductive vias 344 and a DB dielectric is the insulator material 336. For the die 360, DB contacts are conductive contacts 362 of the die 360 and a DB dielectric is an insulator material 364 surrounding the conductive contacts 362 of the die 360.

In some embodiments, the conductive contacts 362 may be, or may be coupled (e.g., directly connected) to interconnect structures 432 of metal layers of the BEOL, as described below with reference to FIG. 9. In other embodiments, the conductive contacts 362 may be, or may be coupled (e.g., directly connected) to various terminals of the active components in a device layer, e.g., to S/D contacts 428 of transistors, as described below with reference to FIG. 10.

One example implementation of the IC device 100 is shown in FIG. 9. FIG. 9 illustrates a cross-sectional side view of an example IC device 400 that may include one or more flipped staircase interconnect structures in accordance with any of the embodiments disclosed herein. The IC device 400 is an example of the IC device 100, as explained below.

The IC device 400 may be formed on a substrate 410, where the substrate 410 may be any suitable support structure as described herein, e.g., the support structure 110 of FIG. 1 and/or the wafer 2000 of FIG. 11. The substrate 410 may be part of a singulated die (e.g., the dies 2002 of FIG. 11) or a wafer (e.g., the wafer 2000 of FIG. 11).

The IC device 400 may include one or more device layers 420 disposed on the substrate 410, where, together, the one or more device layers 420 may be an example of the device layer 120 of the IC device 100. The device layer 420 may include features of one or more transistors 422 (e.g., metal-oxide-semiconductor field-effect transistors (MOSFETs)) formed on the substrate 410. The device layer 420 may include, for example, one or more source and/or drain (S/D) regions 424, a gate 426 to control current flow in the transistors 422 between the S/D regions 424, and one or more S/D contacts 428 to route electrical signals to/from the S/D regions 424. The transistors 422 may include additional features not depicted for the sake of clarity, such as device isolation regions, gate contacts, and the like. The transistors 422 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

The S/D regions 424 may be formed within the substrate 410 adjacent to the gate 426 of each transistor 422, using any suitable processes known in the art. For example, the S/D regions 424 may be formed using either an implantation/diffusion process or a deposition process. In the former process, dopants such as boron, aluminum, antimony, phosphorous, or arsenic may be ion-implanted into the substrate 410 to form the S/D regions 424. An annealing process that activates the dopants and causes them to diffuse farther into the substrate 410 may follow the ion implantation process. In the latter process, an epitaxial deposition process may provide material that is used to fabricate the S/D regions 424. In some implementations, the S/D regions 424 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 424 may be formed using one or more alternate semiconductor materials such as germanium or a group III-V material or alloy. In further embodiments, one or more layers of metal and/or metal alloys may be used to form the S/D regions 424. In some embodiments, an etch process may be performed before the epitaxial deposition to create recesses in the substrate 410 in which the material for the S/D regions 424 is deposited.

Each transistor 422 may include a gate 426 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a P-type metal-oxide-semiconductor (PMOS) or an N-type metal-oxide-semiconductor (NMOS) transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer. For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 422 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 422 may include one layer or a stack of layers, and the one or more layers may include silicon oxide, silicon dioxide, and/or a high-k dielectric material. The high-k dielectric material included in the gate dielectric layer of the transistor 422 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

Electrical signals, such as power and/or input/output (I/O) signals, may be routed to and/or from the transistors 422 of the device layer 420 through one or more metal layers 430 disposed on the device layer 420, illustrated in FIG. 9 as metal layers 430-1, 430-2, and 430-3. For example, electrically conductive features of the device layer 420 (e.g., the gate 426 and the S/D contacts 428) may be electrically coupled with the interconnect structures 432 of the metal layers 430. Although a particular number of metal layers 430 is depicted in FIG. 9, embodiments of the present disclosure include IC devices having more or fewer metal layers than depicted. The one or more metal layers 430 may form a metallization stack 440 of the IC device 400. The metal layers 430 are examples of the metal layers 130 of the IC device 100.

The interconnect structures 432 may be arranged within the metal layers 430 to route electrical signals according to a wide variety of designs (in particular, the arrangement is not limited to the particular configuration of interconnect structures 432 depicted in FIG. 9). In some embodiments, the interconnect structures 432 may include conductive lines 432a and/or conductive vias 432b, formed of an electrically conductive material such as a metal. The conductive lines 432a may be arranged to route electrical signals in a direction of a plane that is substantially parallel with a surface of the substrate 410 upon which the device layer 420 is formed. For example, the conductive lines 432a may route electrical signals in a direction in and out of the page from the perspective of FIG. 9. The conductive vias 432b may be arranged to route electrical signals in a direction of a plane that is substantially perpendicular to the surface of the substrate 410 upon which the device layer 420 is formed. In some embodiments, the conductive vias 432b may electrically couple conductive lines 432a of different metal layers 430 together.

A first metal layer 430-1 (referred to as Metal 1 or “M1”) may be formed directly on the device layer 420. In some embodiments, the first metal layer 430-1 may include conductive lines 432a and/or conductive vias 432b, as shown. The conductive lines 432a of the first metal layer 430-1 may be coupled with contacts (e.g., the S/D contacts 428) of the device layer 420.

A second metal layer 430-2 (referred to as Metal 4 or “M2”) may be formed directly on the first metal layer 430-1. In some embodiments, the second metal layer 430-2 may include conductive vias 432b to couple the conductive lines 432a of the second metal layer 430-2 with the conductive lines 432a of the first metal layer 430-1. Although the conductive lines 432a and the conductive vias 432b are structurally delineated with a line within each metal layer (e.g., within the second metal layer 430-2) for the sake of clarity, the conductive lines 432a and the conductive vias 432b may be structurally and/or materially contiguous (e.g., simultaneously filled during a dual-damascene process) in some embodiments.

A third metal layer 430-3 (referred to as Metal 3 or “M3”) (and additional metal layers, as desired) may be formed in succession on the second metal layer 430-2 according to similar techniques and configurations described in connection with the second metal layer 430-2 or the first metal layer 430-1.

The metal layers 430 may include a dielectric material 434 disposed between the interconnect structures 432, as shown in FIG. 9. The dielectric material 434 may take the form of any of the embodiments of insulator materials disclosed herein, for example any of the embodiments discussed herein with reference to the insulating medium of the metal layers 130. In some embodiments, the dielectric material 434 disposed between the interconnect structures 432 in different ones of the metal layers 430 may have different compositions. In other embodiments, the composition of the dielectric material 434 in different metal layers 430 may be the same.

The IC device 400 may include a solder resist material 436 (e.g., polyimide or similar material) and one or more conductive contacts 438 (e.g., bond pads) formed on the metal layers 430. The conductive contacts 438 may be electrically coupled with the interconnect structures 432 and configured to route the electrical signals of the transistor(s) 422 to other external devices. For example, solder bonds may be formed on the one or more conductive contacts 438 to mechanically and/or electrically couple a chip including the IC device 400 with another component (e.g., a circuit board). The IC device 400 may have other alternative configurations to route the electrical signals from the metal layers 430 than depicted in other embodiments. For example, the conductive contacts 438 illustrated in FIG. 9 as bond pads may be replaced by or may further include other analogous features (e.g., posts) that route the electrical signals to external components.

As shown in FIG. 9, the IC device 400 further includes the flipped staircase interconnect structure 350 bonded to the top metal layer 430 of the metallization stack 440 (i.e., to the metal layer 430-3 in the example shown) by the bonding layer 370. The bonding shown in FIG. 9 is one example of the bonding shown in FIG. 8 and described above. For example, a combination of the substrate 410, the device layer 420, and the metal layers 430 is an example of the die 360 of FIG. 8; the ones of the interconnect structures 432 being bonded to the bonding contacts 372 of the bonding layer 370 are, or include, the conductive contacts 362 of FIG. 8; and the dielectric material 434 of the top metal layer 430 of the IC device 400 is an example of the insulator material 364 of FIG. 8.

One example implementation of the IC device 200 is shown in FIG. 10. FIG. 10 illustrates a cross-sectional side view of an example IC device 500 that may include one or more flipped staircase interconnect structures in accordance with any of the embodiments disclosed herein. The IC device 500 may be substantially the same as the IC device 400, except that it does not include the metallization stack 440. Instead, the bonding layer 370 of the IC device 500 bonds the flipped staircase interconnect structure 350 to the device layer 420. The bonding shown in FIG. 10 is another example of the bonding shown in FIG. 8 and described above. For example, a combination of the substrate 410 and the device layer 420 is an example of the die 360 of FIG. 8; the ones of the S/D contacts 428 and/or various interconnect structures (e.g., conductive vias and/or conductive lines) that may be present in the device layer 420 that are bonded to the bonding contacts 372 of the bonding layer 370 are, or include, the conductive contacts 362 of FIG. 8; and a dielectric material around various interconnect structures of the device layer 420 is an example of the insulator material 364 of FIG. 8.

Various arrangements of the IC devices as illustrated in FIGS. 1-10 do not represent an exhaustive set of IC devices that may implement flipped staircase interconnect structures as described herein, but merely provide examples of such devices/structures/assemblies. In particular, the number and positions of various elements shown in FIGS. 1-10 is purely illustrative and, in various other embodiments, other numbers of these elements, provided in other locations relative to one another may be used in accordance with the general architecture considerations described herein.

Arrangements with an IC device with one or more flipped staircase interconnect structures as disclosed herein may be included in any suitable electronic device. FIGS. 11-15 illustrate various examples of devices and components that may include an IC device with one or more flipped staircase interconnect structures as disclosed herein.

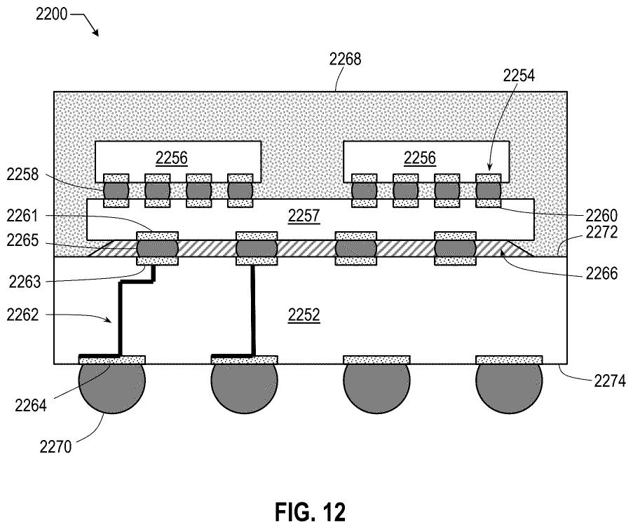

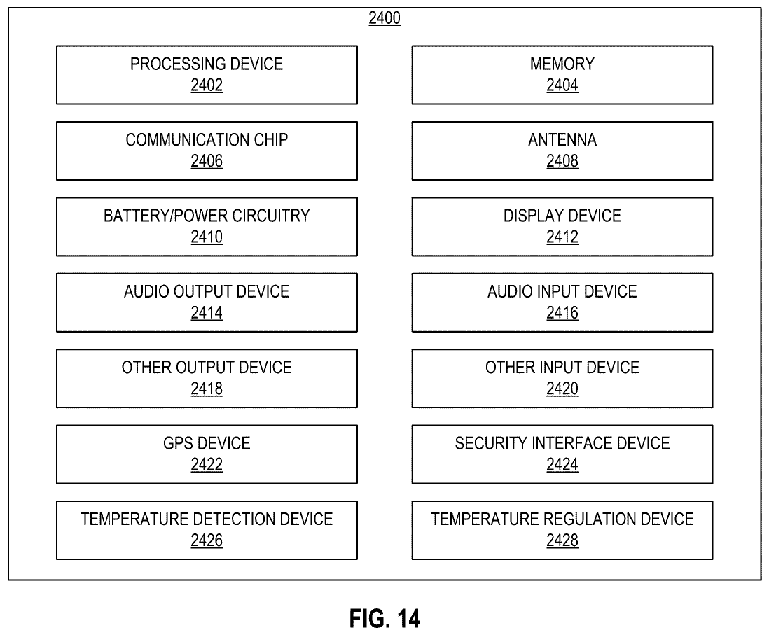

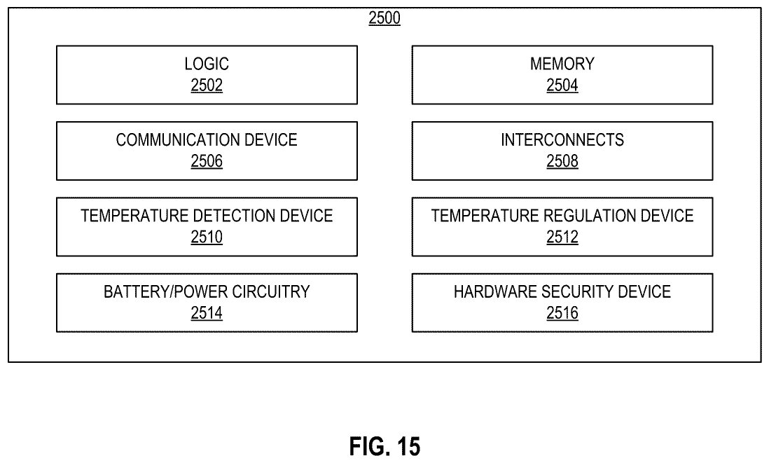

FIG. 11 illustrates top views of a wafer 2000 and dies 2002 that may include an IC device with one or more flipped staircase interconnect structures in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 12. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including an IC device with one or more flipped staircase interconnect structures as described herein). After the fabrication of the semiconductor product is complete (e.g., after manufacture of any embodiment of the IC device 100 as described herein), the wafer 2000 may undergo a singulation process in which each of the dies 2002 is separated from one another to provide discrete “chips” of the semiconductor product. In particular, devices that include an IC device with one or more flipped staircase interconnect structures as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device, a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 14 or the logic 2502 of FIG. 15) or other logic that is configured to store information in the memory devices or execute instructions stored in the memory array.

FIG. 12 is a side, cross-sectional view of an example IC package 2200 that may include an IC device with one or more flipped staircase interconnect structures in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 12 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 12 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

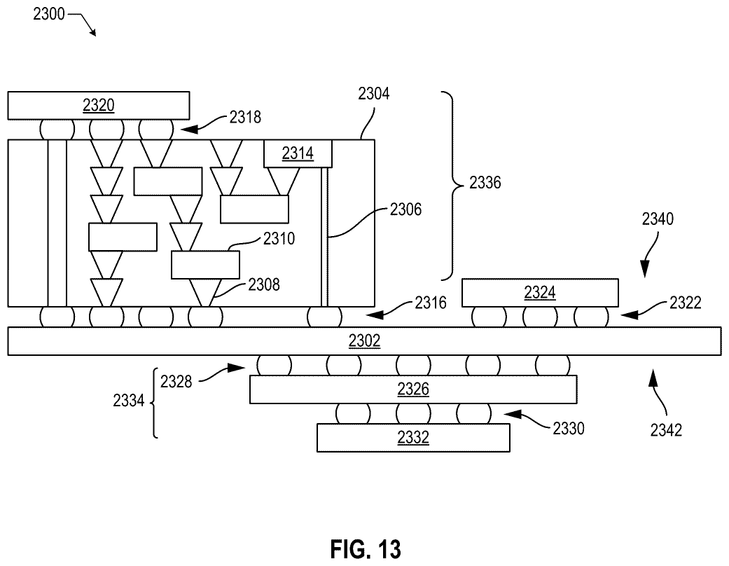

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 12 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 13.

The dies 2256 may take the form of any of the embodiments of the die 2002 discussed herein (e.g., may include any of the embodiments of the IC devices with one or more flipped staircase interconnect structures as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include an IC device with one or more flipped staircase interconnect structures, e.g., as discussed above; in some embodiments, at least some of the dies 2256 may not include any flipped staircase interconnect structures.

The IC package 2200 illustrated in FIG. 12 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 12, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 13 is a cross-sectional side view of an IC device assembly 2300 that may include components having an IC device with one or more flipped staircase interconnect structures in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of an IC device with one or more flipped staircase interconnect structures in accordance with any of the embodiments disclosed herein; e.g., any of the IC packages discussed below with reference to the IC device assembly 2300 may take the form of any of the embodiments of the IC package 2200 discussed above with reference to FIG. 12 (e.g., may include an IC device with one or more flipped staircase interconnect structures provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 13 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 13), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 11), an IC device, or any other suitable component. In particular, the IC package 2320 may include an IC device with one or more flipped staircase interconnect structures as described herein. Although a single IC package 2320 is shown in FIG. 13, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 13, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as RF devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 13 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 14 is a block diagram of an example computing device 2400 that may include one or more components including an IC device with one or more flipped staircase interconnect structures in accordance with any of the embodiments disclosed herein. For example, any suitable ones of the components of the computing device 2400 may include a die (e.g., the die 2002 of FIG. 11) having one or more flipped staircase interconnect structures as described herein. Any one or more of the components of the computing device 2400 may include, or be included in, an IC package 2200 of FIG. 12 or an IC device 2300 of FIG. 13.

A number of components are illustrated in FIG. 14 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 14, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 15 is a block diagram of an example processing device 2500 that may include an IC device with one or more flipped staircase interconnect structures in accordance with any of the embodiments disclosed herein. For example, any suitable ones of the components of the processing device 2500 may include a die (e.g., the die 2002 of FIG. 11) having one or more flipped staircase interconnect structures as described herein. Any one or more of the components of the processing device 2500 may include, or be included in, an IC device 2300 (FIG. 13). Any one or more of the components of the processing device 2500 may include, or be included in, an IC package 2200 of FIG. 12 or an IC device 2300 of FIG. 13. Any one or more of the components of the processing device 2500 may include, or be included in, a computing device 2400 of FIG. 14; for example, the processing device 2500 may be the processing device 2402 of the computing device 2400.

A number of components are illustrated in FIG. 15 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 15, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 14). In some embodiments, the memory 2504 may be a designated device configured to provide storage functionality for the components of the processing device 2500 (e.g., local), while the memory 1604 may be configured to provide system-level storage functionality for the entire computing device 2400 (e.g., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, e.g., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 14). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, MIM structures, etc.

The processing device 2500 may include a temperature detection device 2510 which may be implemented substantially as described above with reference to the temperature detection device 2426 of FIG. 14 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 14 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 14. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 14. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC device that includes a support structure (e.g., a substrate, a die, a wafer, or a chip); a device layer over or at least partially in the support structure, the device layer comprising a plurality of transistors; and an interconnect layer, wherein the device layer is between the support structure and the interconnect layer, the interconnect layer includes a first conductive line and a second conductive line stacked above the first conductive line (i.e., the second conductive line is further away from the device layer than the first conductive line), a first end of the first conductive line is substantially aligned with a first end of the second conductive line along a plane perpendicular to the substrate, and a second end of the first conductive line is closer to the plane than a second end of the second conductive line (i.e., the length of the first conductive line is smaller than the length of the second conductive line).

Example 2 provides the IC device according to example 1, further including an insulator material between the first conductive line and the second conductive line.

Example 3 provides the IC device according to examples 1 or 2, where the interconnect layer is at least a part of a metallization stack of the IC device, and where the first conductive line and the second conductive line are in different metal layers of the metallization stack.

Example 4 provides the IC device according to any one of the preceding examples, where the interconnect layer further includes a third conductive line stacked above the second conductive line (i.e., the third conductive line is further away from the device layer than the second conductive line), a first end of the third conductive line is substantially aligned with the first end of the second conductive line along the plane, and the second end of the second conductive line is closer to the plane than a second end of the third conductive line (i.e., the length of the second conductive line is smaller than the length of the third conductive line).

Example 5 provides the IC device according to example 4, further including an insulator material between the second conductive line and the second third conductive line.

Example 6 provides the IC device according to examples 4 or 5, where the interconnect layer is at least a part of a metallization stack of the IC device, and where the first conductive line, the second conductive line, and the third conductive line are in different metal layers of the metallization stack.

Example 7 provides the IC device according to any one of the preceding examples, further including a conductive via extending from a portion of the first conductive line that is closer to the second end of the first conductive line than to the first end of the first conductive line, the conductive via including a first portion and a second portion, where the first portion of the conductive via is closer to the first conductive line than the second portion of the conductive via, and where a width of the first portion of the conductive via is smaller than a width of the second portion of the conductive via.

Example 8 provides the IC device according to example 7, where the conductive via is a first conductive via, and the IC device further includes a second conductive via extending from a portion of the second conductive line that is closer to the second end of the second conductive line than to the first end of the second conductive line, the second conductive via including a first portion and a second portion, where the first portion of the second conductive via is closer to the second conductive line than the second portion of the second conductive via, and where a width of the first portion of the second conductive via is smaller than a width of the second portion of the second conductive via.

Example 9 provides the IC device according to examples 7 or 8, further including a bonding interface between the interconnect layer and the device layer, where the bonding interface includes a bonding contact and a bonding dielectric, and the via is in conductive contact with the bonding contact.

Example 10 provides the IC device according to example 9, where the bonding contact is a direct bonding contact.

Example 11 provides the IC device according to example 9, where the bonding contact is a hybrid bonding contact.

Example 12 provides the IC device according to any one of examples 9-11, where at least one contact of the device layer is in conductive contact with the bonding contact.

Example 13 provides the IC device according to example 12, where the at least one contact of the device layer is one of a contact to a gate of at least one transistor of the device layer, a contact to a source region of the at least one transistor, or a contact to a drain region of the at least one transistor.

Example 14 provides the IC device according to example 12, where the at least one contact of the device layer is a conductive line or a conductive via of the device layer.

Example 15 provides the IC device according to any one of examples 9-11, further including a metallization stack including a plurality of metal layers, where the metallization stack is between the device layer and the bonding interface, and at least one interconnect structure of a metal layer of the plurality of metal layers that is closest to the bonding interface is in conductive contact with the bonding contact.

Example 16 provides the IC device according to example 15, where the at least one interconnect structure of the metal layer is a conductive line or a conductive via.

Example 17 provides an IC device that includes a die having a surface, where the die includes conductive contacts at the surface; an interconnect structure (e.g., a flipped staircase interconnect structure) including a stack of conductive lines separated by an insulator material; and a bonding interface between the surface and the staircase interconnect structure, where the conductive lines of the stack are in a staircase arrangement with a longest one of the conductive lines being further away from the bonding interface than a shortest one of the conductive lines.

Example 18 provides the IC device according to example 17, further including conductive vias extending from individual ones of the conductive lines, where the conductive vias taper down as the conductive vias extend further away from the bonding interface.

Example 19 provides an IC package that includes an IC device according to any one of the preceding examples; and a further component, coupled to the IC device. For example, the IC device may include an IC die that includes a device layer and an interconnect layer, where the interconnect layer includes a stack of conductive lines separated by an insulator material, and the conductive lines of the stack are in a staircase arrangement with a longest one of the conductive lines being further away from the device layer than a shortest one of the conductive lines.

Example 20 provides the IC package according to example 19, where the further component is or includes one of a package substrate, an interposer, or a further IC die.

In various further examples of the IC package according to examples 19 or 20, the further component may be coupled to the IC die via one or more first-level interconnects, where the one or more first-level interconnects may include one or more solder bumps, solder posts, or bond wires.

In further examples of the IC package according to any of the preceding examples, the IC die includes, or is a part of, at least one of a memory device, a computing device, a wearable device, a handheld electronic device, and a wireless communications device.

Example 21 provides an electronic device that includes a carrier substrate; and one or more of the IC device according to any one of the preceding examples and the IC package according to any one of the preceding examples, coupled to the carrier substrate.

Example 22 provides the electronic device according to example 21, where the carrier substrate is a motherboard.

Example 23 provides the electronic device according to example 21, where the carrier substrate is a PCB.

Example 24 provides the electronic device according to any one of examples 21-23, where the electronic device is a wearable electronic device (e.g., a smart watch) or handheld electronic device (e.g., a mobile phone).

Example 25 provides the electronic device according to any one of examples 21-24, where the electronic device further includes one or more communication chips and an antenna.

Example 26 provides the electronic device according to any one of examples 21-25, where the electronic device is a memory device.

Example 27 provides the electronic device according to any one of examples 21-25, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 28 provides the electronic device according to any one of examples 21-25, where the electronic device is a computing device.

Example 29 provides the electronic device according to any one of examples 21-28, where the electronic device is included in a base station of a wireless communication system.

Example 30 provides the electronic device according to any one of examples 21-28, where the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a substrate;
a device layer over or at least partially in the substrate, the device layer comprising a plurality of transistors; and
an interconnect layer, wherein the device layer is between the substrate and the interconnect layer, the interconnect layer includes a first conductive line and a second conductive line stacked above the first conductive line, a first end of the first conductive line is substantially aligned with a first end of the second conductive line along a plane perpendicular to the substrate, and a second end of the first conductive line is closer to the plane than a second end of the second conductive line.

2. The IC device according to claim 1, further comprising an insulator material between the first conductive line and the second conductive line.

3. The IC device according to claim 1, wherein the interconnect layer is at least a part of a metallization stack of the IC device, and wherein the first conductive line and the second conductive line are in different metal layers of the metallization stack.

4. The IC device according to claim 1, wherein the interconnect layer further includes a third conductive line stacked above the second conductive line, a first end of the third conductive line is substantially aligned with the first end of the second conductive line along the plane, and the second end of the second conductive line is closer to the plane than a second end of the third conductive line.

5. The IC device according to claim 4, further comprising an insulator material between the second conductive line and the second third conductive line.

6. The IC device according to claim 4, wherein the interconnect layer is at least a part of a metallization stack of the IC device, and wherein the first conductive line, the second conductive line, and the third conductive line are in different metal layers of the metallization stack.

7. The IC device according to claim 1, further comprising a conductive via extending from a portion of the first conductive line that is closer to the second end of the first conductive line than to the first end of the first conductive line, the conductive via comprising a first portion and a second portion, wherein:
the first portion of the conductive via is closer to the first conductive line than the second portion of the conductive via, and
a width of the first portion of the conductive via is smaller than a width of the second portion of the conductive via.

8. The IC device according to claim 7, wherein the conductive via is a first conductive via, and the IC device further includes a second conductive via extending from a portion of the second conductive line that is closer to the second end of the second conductive line than to the first end of the second conductive line, the second conductive via comprising a first portion and a second portion, wherein:
the first portion of the second conductive via is closer to the second conductive line than the second portion of the second conductive via, and
a width of the first portion of the second conductive via is smaller than a width of the second portion of the second conductive via.

9. The IC device according to claim 7, further comprising a bonding interface between the interconnect layer and the device layer, wherein:
the bonding interface includes a bonding contact and a bonding dielectric, and
the via is in conductive contact with the bonding contact.

10. The IC device according to claim 9, wherein the bonding contact is a direct bonding contact.

11. The IC device according to claim 9, wherein the bonding contact is a hybrid bonding contact.

12. The IC device according to claim 9, wherein at least one contact of the device layer is in conductive contact with the bonding contact.

13. The IC device according to claim 12, wherein the at least one contact of the device layer is one of a contact to a gate of at least one transistor of the device layer, a contact to a source region of the at least one transistor, or a contact to a drain region of the at least one transistor.

14. The IC device according to claim 12, wherein the at least one contact of the device layer is a conductive line or a conductive via of the device layer.

15. The IC device according to claim 9, further comprising a metallization stack comprising a plurality of metal layers, wherein the metallization stack is between the device layer and the bonding interface, and at least one interconnect structure of a metal layer of the plurality of metal layers that is closest to the bonding interface is in conductive contact with the bonding contact.

16. The IC device according to claim 15, wherein the at least one interconnect structure of the metal layer is a conductive line or a conductive via.

17. An integrated circuit (IC) device, comprising:
a die having a surface, wherein the die includes conductive contacts at the surface;
an interconnect structure comprising a stack of conductive lines separated by an insulator material; and
a bonding interface between the surface and the staircase interconnect structure,
wherein the conductive lines of the stack are in a staircase arrangement with a longest one of the conductive lines being further away from the bonding interface than a shortest one of the conductive lines.

18. The IC device according to claim 17, further comprising conductive vias extending from individual ones of the conductive lines, wherein the conductive vias taper down as the conductive vias extend further away from the bonding interface.

19. An integrated circuit (IC) package, comprising:
an IC die; and
a further component, coupled to the IC die,
wherein the IC die includes a device layer and an interconnect layer, the interconnect layer includes a stack of conductive lines separated by an insulator material, and the conductive lines of the stack are in a staircase arrangement with a longest one of the conductive lines being further away from the device layer than a shortest one of the conductive lines.

20. The IC package according to claim 19, wherein the further component is one of a package substrate, an interposer, or a further IC die.
